(19) United States
(12) Patent Application Publication
(10) Pub. No.: US 2014/0151885 A1
(43) Pub. Date: Jun. 5, 2014

(54) SEMICONDUCTOR DEVICE AND METHOD FOR MANUFACTURING A SEMICONDUCTOR DEVICE

(71) Applicant: Timo Benzel, Pliezhausen (DE)

(72) Inventors: Peter SCHMOLLNGRUBER, Aidlingen (DE); Hubert BENZEL, Pliezhausen (DE); Hans ARTMANN, Boeblingen (DE); Viktor MOROSOW, Reutlingen (DE)

(73) Assignee: ROBERT BOSCH GMBH, Stuttgart (DE)

(21) Appl. No.: 14/012,211

(22) Filed: Aug. 28, 2013

(30) Foreign Application Priority Data
Aug. 28, 2012 (DE) 10 2012 215 233.4

(51) Int. Cl. H01L 23/532; H01L 21/768

(52) U.S. Cl. CPC H01L 23/53266; H01L 21/7685
USPC 257/751; 438/643

(57) ABSTRACT

A semiconductor device includes a substrate which has at least one doped contact area and at least one line which is formed on the substrate and which is electrically connected to the at least one contact area, and at least one diffusion barrier, which includes at least one metal applied on a contact surface of the associated contact area, being formed between the at least one line and the at least one associated contact area, the at least one metal forming multiple metal-plated subareas which contact the contact surface of the same contact area and which are separated from one another. Furthermore, a manufacturing method for a semiconductor device is described.

### CROSS REFERENCE TO RELATED APPLICATION

The present application claims priority to Application No. DE 10 2012 215 233.4, filed in the Federal Republic of Germany on Aug. 28, 2012, which is expressly incorporated herein in its entirety by reference thereto.

### FIELD OF INVENTION

The present invention relates to a semiconductor device. Furthermore, the present invention relates to a manufacturing method for a semiconductor device.

### BACKGROUND INFORMATION

European Application No. EP 1 760 442 describes a pressure sensor which has a semiconductor substrate having a doped contact area. For forming a diffusion barrier, a tantalum silicon layer is applied on the doped contact area which is covered by a tantalum layer. A line made of a conductive material electrically connects the doped contact area to a bond wire.

### SUMMARY

The present invention provides a semiconductor device and a manufacturing method for a semiconductor device.

The formation of multiple metal-plated subareas which are separated from one another and each of which contacts (directly) the contact surface of the same contact area improves the media resistance of the at least one metal of the metal-plated subareas even in the case of damage to the passivation of these. In the case of damage to the passivation, only the at least one metal-plated subarea, which is potentially exposed, is subjected to the surrounding atmosphere. Since the remaining metal-plated subareas of the same contact area are separate, however, an indirect reaction of the at least one metal of the remaining metal-plated subareas with the environment is reliably prevented. The remaining metal-plated subareas are therefore still protected by the passivation and may thus reliably carry out their function. In this way, use of the at least one associated line is still ensured with the aid of the metal-plated subareas which are still functional despite the damage to the passivation.

Moreover, the formation of multiple metal-plated subareas which are separated from one another and all of which (directly) contact the same contact surface of an associated contact area reduce the mechanical stress conventionally frequently occurring during a temperature change. In this way, the semiconductor device, which is equipped with multiple metal-plated subareas which are separated from one another, may also be used in an environment where a significant temperature change frequently occurs.

In one advantageous exemplary embodiment, the multiple metal-plated subareas contacting the contact surface of the same contact area are offset laterally to one another. A laterally offset design of the metal-plated subareas may be understood to mean that the metal-plated subareas are arranged in a raster to one another, each of the two adjacent metal-plated subareas of the same contact surface being offset to one another in a direction which is upward parallel to a substrate surface. Such a configuration ensures the advantages already described above of an advantageous media resistance, a reduced mechanical stress, and a comparably large total adhesive surface.

In another advantageous exemplary embodiment, at least one gap between two metal-plated subareas which (directly) contact the contact surface of the same contact area and are adjacent to one another is filled with at least one other material as the at least one metal of the metal-plated subareas. In particular, the material filled into the at least one gap may include at least one diffusion barrier material. The above-mentioned advantages of an improved media resistance, a reduced mechanical stress, and a comparably large total adhesive surface are thus achievable in a simple manner.

For example, the at least one metal (of the separated metal-plated subareas) may include titanium, tantalum, platinum, chromium, and/or aluminum. The present invention is thus employable with a plurality of metals usable for metal plating.

In another advantageous exemplary embodiment, at least one diffusion barrier (of the diffusion barriers)/the diffusion barrier includes a one-piece metal-plated contact layer which contacts multiple metal-plated subareas which (directly) contact the contact surface of the associated contact area. In this way, an adhesion of the metal-plated subareas, which are separated from one another, on a contact surface is improved. The easily formable metal-plated contact layer thus keeps the metal-plated subareas on the substrate.

In this case, the one-piece metal-plated contact layer is advantageously a tantalum layer. The use of tantalum (optionally including tantalum nitride) ensures an advantageous media resistance of the at least one metal-plated contact layer.

Moreover, the at least one metal (of the separated metal-plated subareas) may be platinum. By forming multiple metal-plated subareas, which are separated from one another, on the same contact surface, the different expansion coefficients of the used materials can hardly/not at all contribute to an occurrence of mechanical stress even in the case of a great temperature change.

In one alternative or supplementing exemplary embodiment, at least one diffusion barrier (of the diffusion barriers)/the diffusion barrier includes multiple metal-plated contact sublayers, which are separated from one another, each of the metal-plated contact sublayers contacting one of multiple metal-plated subareas (directly) contacting the contact surface of the associated contact area. Such an application of the at least one material of the metal-plated contact sublayers may improve its media resistance. Likewise, a mechanical stress may be reduced in this way which occurs in the at least one material of the metal-plated contact sublayers. Moreover, the laterally offset configuration/formation of the metal-plated contact sublayers allows for a larger total adhesive surface thereof.

In this case, the metal-plated contact sublayers are preferably made of titanium nitride. The at least one metal may be titanium. By advantageously applying the materials titanium and titanium nitride, an improved protection of these materials is, however, provided in this case. In this way, the materials may also be used in corrosive environments, even if damage to their passivation is not completely excluded. As already stated above, a complete etching of the materials titanium and titanium nitride by corrosive media of the environment is reliably prevented even if there is a risk of partial damage to the passivation.

The above-described advantages are also ensured in the case of a manufacturing method for a semiconductor device which is accordingly refined.

### BRIEF DESCRIPTION OF THE DRAWINGS

Additional features and advantages of exemplary embodiments of the present invention are explained in the following with reference to the accompanying drawings.

FIGS. 1a and 1b show schematic whole and partial illustrations of a first exemplary embodiment of the semiconductor device.

FIG. 2 shows a schematic partial illustration of a second exemplary embodiment of the semiconductor device.

FIGS. 3a and 3b show schematic whole and partial illustrations of a third exemplary embodiment of the semiconductor device.

FIGS. 4a through 4d show schematic whole and partial illustrations of a fourth exemplary embodiment of the semiconductor device.

FIG. 5 shows a flow chart to illustrate an exemplary embodiment of the manufacturing method.

### DETAILED DESCRIPTION

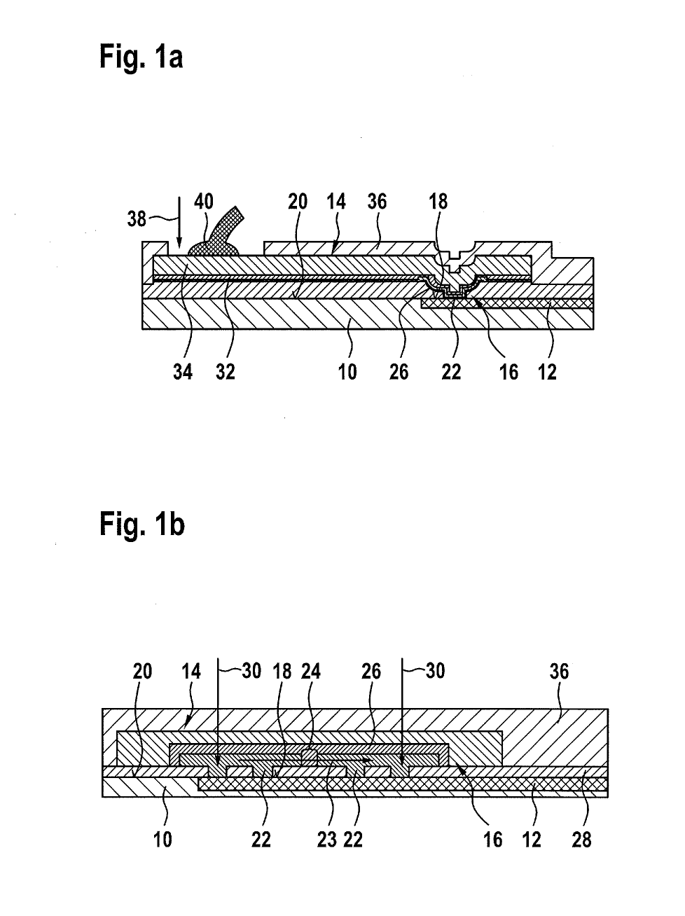

FIGS. 1a and 1b show schematic whole and partial illustrations of a first exemplary embodiment of the semiconductor device.

The semiconductor device represented schematically in FIGS. 1a and 1b has a substrate 10 having at least one doped contact area 12. Substrate 10 preferably includes a semiconductor material, such as silicon. In particular, substrate 10 may be a silicon substrate. Instead of or in addition to the silicon, substrate 10 may, however, also include a different material. In particular, substrate 10 may additionally also be formed from at least one other semiconductor material and/or at least one non-semiconductor material.

The at least one contact area 12 may have implanted ions and be conductive. Preferably, the at least one contact area 12 is designed such that its doping is introduced directly under a contact surface 18 of the particular contact area 12. Contact surface 18 may be understood to mean a partial surface of a substrate surface 20 of substrate 10 which is on and/or above the particular contact area 12.

At least one line 14 which is electrically connected to the at least one contact area 12 is formed on substrate 10. For example, the at least one line 14 also runs above the at least one contact surface 18. In particular, the at least one line 14 may end/start above the at least one contact surface 18 of the at least one contact area 12.

At least one diffusion barrier 16 is formed between the at least one line 14 and the at least one associated contact area 12. The at least one diffusion barrier 16 includes at least one metal which is (directly) applied on contact surface 18 of associated contact area 12. In other words, at least one metal of diffusion barrier 16 (directly) contacts/touches contact surface 18.

The at least one metal of diffusion barrier 16 forms multiple metal-plated subareas 22 which (directly) contact contact surface 18 of the same contact area 12 and which are separated from one another. Diffusion barrier 16 of a line 14/a contact area 12 thus includes multiple metal-plated subareas 22 which are separated from one another.

Metal-plated subareas 22 of the same diffusion barrier 16 (i.e., on a contact surface 18 of a single contact area 12) have the same metal or the same composition of at least two metals. A separate formation of metal-plated subareas 22 may be understood to mean that metal-plated subareas 22 (of the same diffusion barrier 16) which are situated (directly) on contact surface 18 of the same contact area 12 do not form a one-piece (total) metal plating. Instead, metal-plated subareas 22 may be described as a segmented/subdivided metal plating of the same diffusion barrier 16.

For example, multiple metal-plated subareas 22 which (directly) contact contact surface 18 of the same contact area 12/are associated with the same diffusion barrier 16 may also be offset laterally with respect to one another. As is apparent from FIG. 1b, a first metal-plated subarea 22 is thus offset with regard to a second metal-plated subarea 22 on the same contact surface 18/the same diffusion barrier 16 in a direction 23 oriented in parallel to substrate surface 20. In particular, at least one gap 24 between two metal-plated subareas 22, which (directly) contact contact surface 18 of the same contact area 12/are associated with the same diffusion barrier 16 and are adjacent to one another, may be filled with at least one other material than the at least one metal of metal-plated subareas 22. The at least one gap 24 thus subdivides the metal plating of a diffusion barrier 16/on a contact surface 18 of the same contact area 12 into multiple metal-plated subareas 22.

It is pointed out here that metal-plated subareas 22, which are separated from one another, of the same diffusion barrier 16/on the same contact surface 18 of only one contact area 12 are preferably not to be understood to mean metal areas which are stacked one above the other along an axis which is oriented perpendicularly to substrate surface 20. Metal-plated subareas 22, which are associated with the same diffusion barrier 16 and/or touch contact surface 18 of the same contact area 12, do not touch. Moreover, metal-plated subareas 22 of the same diffusion barrier 16 and/or on the same contact surface 18 of a single contact area 12 are not connected to one another, not even via a connecting component which has the same (only) metal or the same material composition of at least two metals as metal-plated subareas 22.

It is pointed out again that metal-plated subareas 22 are to be understood to mean metal-plated areas which are formed from the same single metal/having the same metal composition. Metal-plated subareas 22 are thus not to be understood to mean metal-plated areas formed from different metals or having different metal compositions.

The formation of multiple metal-plated subareas 22, which are separated from one another and which are associated with same diffusion barrier 16 and/or (directly) contact/touch contact surface 18 of the same contact area 12, ensures an improved media resistance of the (segmented) metal plating of diffusion barrier 16. If the metal plating of diffusion barrier 16 is subdivided into multiple metal-plated subareas 22, which are separated from one another, only the material areas, which are exposed (directly) to a surrounding atmosphere, of metal-plated subareas 22 execute a chemical reaction in the case of damage to the passivation of associated diffusion barrier 16. Even if a first metal-plated subarea 22 is exposed to the surrounding atmosphere due to damage to the passivation and chemically reacts with this surrounding atmosphere, a chemical reaction of an adjacent second metal-plated subarea 22 is reliably prevented due to the separation of first metal-plated subarea 22 from second metal-plated subarea 22 until second metal-plated subarea 22 is also directly exposed to the surrounding atmosphere. Since the damage occurring in a passivation, however, does usually not expand very far, it may often be assumed that adjacent second metal-plated subarea 22 is still reliably insulated from a surrounding atmosphere by the passivation despite an at least partial exposure of first metal-plated subarea 22. As a result of the separation of first metal-plated subarea 22 from second metal-plated subarea 22, an indirect influence of second metal-plated subarea 22 by the at least partial exposure of first metal-plated subarea 22 is additionally prevented. Thus, even in the case of damage to the passivation of a diffusion barrier 16, there are still undamaged metal-plated subareas 22 of the same diffusion barrier 16 which reliably ensure a connection/contacting of associated line 14 to the particular contact area 12 via diffusion barrier 16 which lies in-between.

Moreover, the separate formation of metal-plated subareas 22 causes comparably little mechanical stress in the at least one metal, from which metal-plated subareas 22 are formed, even in the case of a significant temperature change.

In the exemplary embodiment of FIGS. 1a and 1b, the at least one metal of metal-plated subareas 22 is platinum. Metal-plated subareas 22 may, however, also be formed from a metal other than platinum. Alternatively or additionally to the material platinum, metal-plated subareas 22 may also include titanium, tantalum, chromium, and/or aluminum. Other metals are also suitable to form metal-plated subareas 22. For all metals listed here, the separate formation of metal-plated subareas 22 of the same diffusion barrier 16/(directly) on the same contact surface 18 of a single contact area 12 ensures the above-described advantages.

The material filled into the at least one gap 24 may advantageously include a non-metal. In particular, the material filled into the at least one gap 24 may include at least one diffusion barrier material, i.e., a material of another component of diffusion barrier 16. The formation of metal-plated subareas 22, which are separated from one another, directly on the same contact surface 18/for the same diffusion barrier 16 is thus implementable without the additional effort of applying additional material.

Diffusion barrier 16 illustrated in an enlarged manner in FIG. 1b includes a one-piece metal-plated contact layer 26 which contacts multiple metal-plated subareas 22 which (directly) contact contact surface 18 of associated contact area 12/are associated with the same diffusion barrier 16. One-piece metal-plated contact layer 26 is preferably a tantalum layer. Optionally, metal-plated contact layer 26 may also be covered by a tantalum nitride layer (not shown) and by another tantalum layer (not illustrated). The list of the materials for diffusion barrier 16 is, however, to be interpreted only by way of example.

With the aid of metal-plated contact layer 26 protruding into gap volume 24, metal-plated subareas 22 may be additionally “held.” In this way, a reliable adhesion of these metal-plated subareas 22 on substrate surface 20 is ensured, even if a poorly adhesive material is used for metal-plated subareas 22.

In the exemplary embodiment of FIGS. 1a and 1b, substrate surface 20 is at least partially covered by an insulating layer 28. Insulating layer 28 may be a silicon dioxide layer, a TEOS layer and/or a BPSG layer, for example. Multiple continuous recesses 30 are formed in insulating layer 28 at least above contact surface 18 of the at least one contact area 12, whereby at least subareas of contact surface 18 are not covered by the material of insulating layer 28. Preferably, continuous recesses 30 are filled with the at least one metal of metal-plated subareas 22, whereby a good electrical contact is ensured between the at least one contact area 12 and associated diffusion barrier 16. In particular, a metal-plated subarea 22 may cover multiple recesses 30 in insulating layer 28. This improves the adhesion of a metal-plated subarea 22 despite its comparably small design. Moreover, the at least one gap volume 24 may be at least partially filled with the at least one material of insulating layer 28. Due to the multifunctionality of insulating layer 28, additional materials may be saved. The material of metal-plated contact layer 26 may also be used to at least partially fill the at least one gap volume 24/gap.

The at least one line 14 may be made of aluminum, platinum and or gold. The at least one line may, however, also be made of other conductive materials than the ones listed here. For example, the at least one line 14 may also be made of a combination of multiple metals. In the exemplary embodiment of FIGS. 1a and 1b, line 14 is formed by applying multiple layers: a platinum layer 32 and a gold layer 34 applied on platinum layer 32. The materials, listed here, of layers 32 and 34 may be easily used to form the at least one line 14 having good conductivity.

Optionally, the at least one diffusion barrier 16 and/or the at least one line 14 may be covered at least partially by a passivation layer 36. Suitable materials for passivation layer 36 are, for example, silicon nitride, silicon dioxide, and/or a silicon nitride-oxide mixture. Further materials are also usable to form the at least one passivation layer 36. Due to the advantageous robustness of the at least one diffusion barrier 16 by forming metal-plated subareas 22 separately from one another, the at least one passivation layer 36 may be designed comparably easily. Sometimes, the formation of the at least one passivation layer 36 may also be dispensed with in this case.

Moreover, the at least one passivation layer 36 may have at least one recess 38 which exposes a subarea of a line 14 lying underneath. The at least one recess 38 may, for example, be used to attach a bond ball 40 to at least partially exposed line 14.

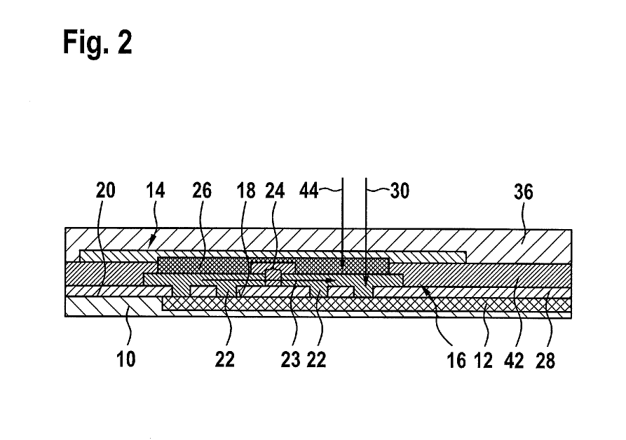

FIG. 2 shows a schematic partial illustration of a second exemplary embodiment of the semiconductor device.

The semiconductor device represented in FIG. 2 by its enlarged diffusion barrier 16 has components 10, 12, 14, 16, 22, 26, 28 and 32 through 36 already described above. In addition, a dielectric intermediate adhesive layer 42 is also deposited above insulating layer 28. The at least one material of dielectric intermediate adhesive layer 42 may also be used to fill gap volume 24/gap at least partially. Due to this multifunctionality of dielectric intermediate adhesive layer 42, additional materials may be saved.

Dielectric intermediate adhesive layer 42 may be a silicon nitride layer, a silicon dioxide layer, a silicon nitride-oxide mixture layer and/or a silicon carbon layer, for example. Other dielectric materials are also suitable for use for dielectric intermediate adhesive layer 42. Recesses 44 are formed in intermediate adhesive layer 42 which expose at least subareas of metal-plated subareas 22 not covered by the material of dielectric intermediate adhesive layer 42. In this way a good reliable contact is ensured between metal-plated subareas 22 and metal-plated contact layer 26 despite dielectric intermediate adhesive layer 42.

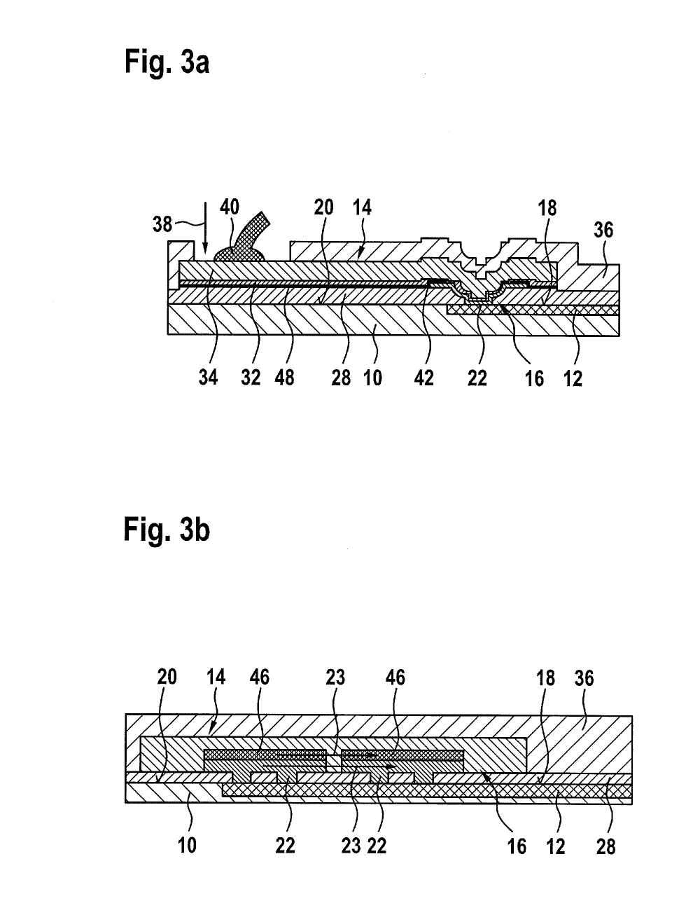

FIGS. 3a and 3b show schematic whole and partial illustrations of a third exemplary embodiment of the semiconductor device.

The semiconductor device represented schematically in FIGS. 3a and 3b has metal-plated subareas 22 made of titanium. For this reason, associated diffusion barrier 16 includes multiple metal-plated contact sublayers 46 which are separated from one another and which are made of titanium nitride. Every metal-plated contact sublayer 46 each contacts one of multiple metal-plated subareas 22 which contact contact surface 18 of associated contact area 12. This may also be referred to as a laterally offset formation of metal-plated contact sublayers 46 which are associated with one single diffusion barrier 16. Optionally, further titanium subareas may be formed which are laterally offset such that every titanium subarea each covers at least partially one of metal-plated contact sublayers 46.

The advantageous design of metal-plated subareas 22 made of titanium and represented in an enlarged manner in FIG. 3b and the advantageous design of metal-plated contact sublayers 46 made of titanium nitride ensure the improved material resistance/robustness of diffusion barrier 16 already explained above. In this way, the semiconductor device having diffusion barrier 16 made of titanium and titanium nitride may also be used in an environment having strongly corrosive substances. The technology according to the present invention described here thus expands the usability of a diffusion barrier 16 made of the materials titanium and titanium nitride. While conventionally, only diffusion barriers 16 containing tantalum and tantalum nitride are principally usable in an environment having strongly corrosive substances, titanium and titanium nitride may also be used for diffusion barriers 16 employed in such conditions by using the technology according to the present invention. In addition, metal-plated subareas 22 made of titanium and metal-plated contact sublayers 46 made of titanium nitride each have a larger adhesive surface than one-piece/recess-free titanium and titanium nitride layers of the same volume and layer thicknesses. For this reason, good adhesion of the materials titanium and titanium nitride is ensured in the design represented here.

An adhesive layer 48 is inserted between insulating layer 28 and platinum layer 32 as a refinement. Optionally, the semiconductor device may also have dielectric intermediate adhesive layer 42.

The above-described semi-conductor devices may be used for a comparably long service life due to the advantageous media resistance of their diffusion barriers 16, the reduced mechanical stress occurring therein, and the advantageous layer adhesion of the materials of diffusion barriers 16. The semiconductor devices are also suitable for use in environments having highly corrosive media stresses and/or comparably high operating temperatures/temperature fluctuations. For example, the semiconductor devices may also carry out their function in an exhaust gas recirculation system and/or in an intake manifold. The semiconductor devices are thus suitable for use as sensors, e.g., a differential pressure sensor, a relative pressure sensor, or an absolute pressure sensor. A sensor module equipped with the semiconductor device may be integrated into a diesel particulate filter, for example.

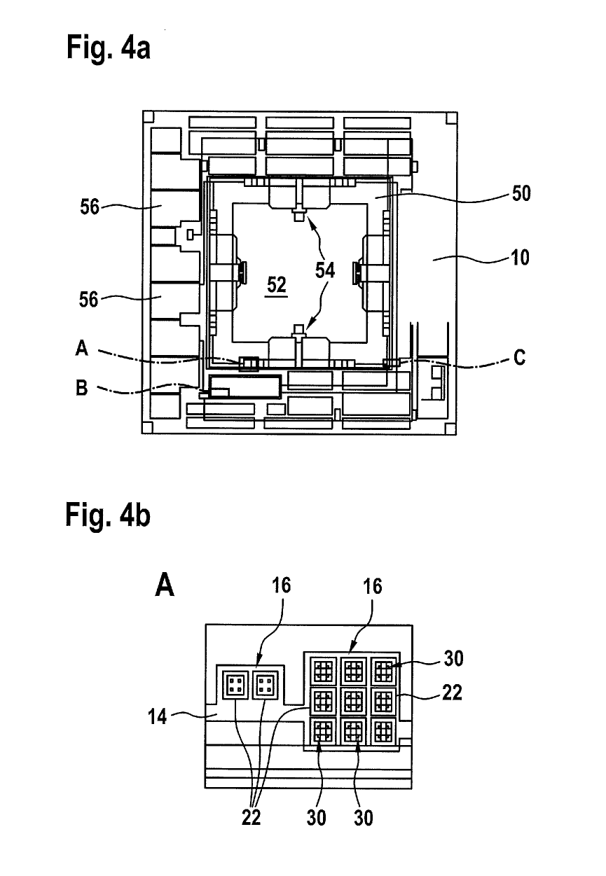

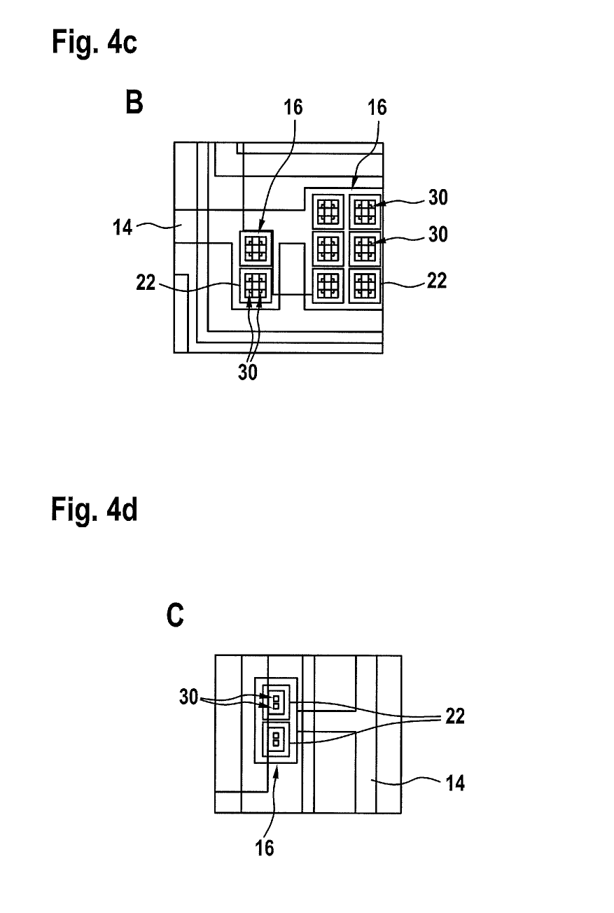

FIGS. 4a through 4d show schematic whole and partial illustrations of a fourth exemplary embodiment of the semiconductor device.

The semiconductor device illustrated schematically in FIGS. 4a through 4d is designed as a pressure sensor. For this purpose, a diaphragm 52, whose shape is a function of a pressure in a volume which is partially limited by diaphragm 52, is spanned on a retaining frame 50 of the semiconductor device. A bulge and/or a concavity of diaphragm 52 is ascertainable with the aid of at least one piezoelectric sensor 54. Multiple bond pads 56 and lines 14 are formed on substrate 10 of the semiconductor device. Contact areas (not illustrated) are buried in substrate 10.

As is apparent from the enlarged subareas A through C in FIGS. 4b through 4d, diffusion barriers 16 are each equipped with multiple metal-plated subareas 22, which are designed separately from one another and which are laterally offset to one another. These may also be referred to as arrays of metal-plated subareas 22.

In particular, a metal-plated subarea 22 may cover multiple recesses 30 in the insulating layer (not illustrated). This improves the adhesion of a metal-plated subarea 22 despite its comparably small design.

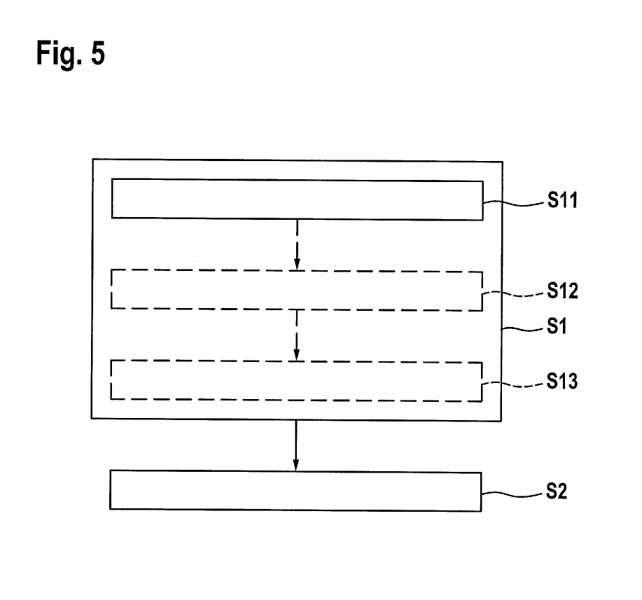

FIG. 5 shows a flow chart to illustrate an exemplary embodiment of the manufacturing method.

The above-described semiconductor devices are manufacturable, for example, with the aid of the manufacturing method described below. The executability of the manufacturing method is, however, not limited to the manufacture of one of these semiconductor devices.

In a method step S1, at least one diffusion barrier is formed on at least one doped contact area of a substrate. For this purpose, at least one metal is (directly) applied on a contact surface of the associated contact area in a substep S11. The at least one metal is applied such that multiple metal-plated subareas which (directly) contact the contact surface of the same contact area and which are separated from one another are formed from the at least one metal.

In one optional substep S12, a one-piece metal-plated contact layer may also be formed which (directly) contacts the multiple metal-plated subareas contacting the contact surface of the same contact area. Alternatively or additionally (to another diffusion barrier), it is also possible that multiple metal-plated contact sublayers, which are separated from one another, of at least one diffusion barrier are formed in a method step S13. This takes place such that every metal-plated contact sublayer each contacts a metal-plated subarea of multiple metal-plated subareas contacting the contact surface of the same contact area.

In another method step S2, at least one line is formed on the substrate such that the at least one diffusion barrier lies between the at least one line and the at least one contact area, and the at least one line is electrically connected to the at least one contact area.

The execution of the manufacturing method described here ensures the above-described advantages. The advantages will not be described here again.

What is claimed is:

1. A semiconductor device, comprising:
a substrate having at least one doped contact area; and
at least one line formed on the substrate and electrically connected to the at least one contact area, at least one diffusion barrier, which includes at least one metal applied on a contact surface of the associated contact area, being formed between the at least one line and the at least one associated contact area;
wherein the at least one metal forms multiple metal-plated subareas which contact the contact surface of the same contact area and which are separated from one another.

2. The semiconductor device according to claim 1, wherein the multiple metal-plated subareas which contact the contact surface of the same contact area are offset laterally.

3. The semiconductor device according to claim 1, wherein at least one gap between two metal-plated subareas, which contact the contact surface of the same contact area and are adjacent to one another, is filled with at least one other material than the at least one metal of metal-plated subareas.

4. The semiconductor device according to claim 3, wherein the material filled into the at least one gap includes at least one diffusion barrier material.

5. The semiconductor device according to claim 1, wherein the at least one metal includes titanium, tantalum, platinum, chromium, and/or aluminum.

6. The semiconductor device according to claim 1, wherein the at least one diffusion barrier includes a one-piece metal-plated contact layer which contacts multiple metal-contact subareas contacting the contact surface of the associated contact area.

7. The semiconductor device according to claim 6, wherein the one-piece metal-plated contact layer is a tantalum layer.

8. The semiconductor device according to claim 6, wherein the at least one metal is platinum.

9. The semiconductor device according to claim 1, wherein the at least one diffusion barrier includes multiple metal-plated contact sublayers which are separated from one another, each metal-plated contact sublayer contacting one of multiple metal-plated subareas contacting the contact surface of the associated contact area.

10. The semiconductor device according to claim 9, wherein the metal-plated contact sublayers are made of titanium nitride.

11. The semiconductor device according to claim 9, wherein the at least one metal is titanium.

12. A manufacturing method for a semiconductor device, comprising:
forming at least one diffusion barrier on at least one doped contact area of a substrate, at least one metal being applied on a contact surface of the associated contact area;
forming at least one line on the substrate such that the at least one diffusion barrier lies between the at least one line and the at least one contact area, and the at least one line is electrically connected to the at least one contact area; and
forming from the at least one metal multiple metal-plated subareas which contact the contact surface of the same contact area and which are separated from one another.

13. The method according to claim 12, further comprising:
forming a one-piece metal-plated contact layer of the at least one diffusion barrier which contacts the multiple metal-plated subareas contacting the contact surface of the same contact area.

14. The method according to claim 12, further comprising:
forming multiple metal-plated contact sublayers, which are separated from one another, of the at least one diffusion barrier, each metal-plated contact sublayer contacting one metal-plated subarea of the multiple metal-plated subareas contacting the contact surface of the same contact area.
